(19) United States
(12) Patent Application Publication
(10) Pub. No.: US 2023/0029904 A1
(43) Pub. Date: Feb. 2, 2023

(54) Method and System for Parameterization of a Plant Model

(71) Applicant: Siemens Aktiengesellschaft, Muenchen (DE)

(72) Inventors: Manuel METTENLEITER, Erlangen (DE); Nicolai HÖHLEIN, Nürnberg (DE)

(21) Appl. No.: 17/789,846

(22) PCT Filed: Dec. 24, 2020
(86) PCT No.: PCT/EP2020/087887

§ 371 Date: Jun. 29, 2022

(30) Foreign Application Priority Data
Dec. 30, 2019 (EP) 19220049

(51) Int. Cl. G06F 30/13

(52) U.S. Cl. CPC G06F 30/13

(57) ABSTRACT

A method and system for parameterization of a plant model, wherein a model of a plant consisting of a plurality of model components, which represent physical sub-processes of the plant process and which correspond to physical models, is provided and at least one output value is specified in an operating point of the plant, where input values, parameter values and/or additional output values of the sub-processes are determined based on the model components and the at least one specified output value.

### CROSS-REFERENCE TO RELATED APPLICATIONS

This is a U.S. national stage of application No. PCT/EP2020/087887 filed 24 Dec. 2020. Priority is claimed on European Application No. 19220049.1 filed 30 Dec. 2019, the content of which is incorporated herein by reference in its entirety.

### BACKGROUND OF THE INVENTION

### 1. Field of the Invention

The present invention relates to a method and a system for parameterization of a plant model.

### 2. Description of the Related Art

Simulations of processes play an ever larger role, for example, in plant planning but also in plant operation. Different simulation approaches are known for different use cases: physical models describe the plant, in particular the different plant components, with the aid of equations, which are based on physical laws, such as conservations principles. Such models are often complex. For example, such models include a large number of parameters, which must be carefully set in order to use the model in the framework of a simulation of the plant.

What are known as “Blackbox” models are limited, by contrast, to the replication of the input and output behaviors of the plant components without replicating physical connections or the describing equations in detail. In the case of phenomenological models, a variant of the “Blackbox” model, for example, the physical connections are reduced to their central dynamics, so only a few characteristic quantities can be set for scaling the models. Other approaches use artificial intelligence to arrive with the aid of existing data at the desired input and output behavior. Despite certain advantages of “Blackbox” models as compared to physical models there remains, on the other hand, the drawback that they do not deliver the same precision or can only replicate the behavior learned with existing data.

### SUMMARY OF THE INVENTION

It is an object of the invention to simplify the application of plan models.

This and other objects and advantages are achieved in accordance with the invention by a method and a system for parameterization of a plant model in accordance with the independent claims.

In a, in particular computer-implemented, method for parameterization of a plant model in accordance with a first aspect of the invention, a model or sub-model of a plant comprising one or more model component(s), which map physical sub-processes of the plant process, is provided and at least one output variable value is specified in an operating point of the plant. In addition, input variable values and/or parameter values and/or further output variable values of the sub-processes are ascertained based on the model components and the at least one specified output variable value.

A plant model within the meaning of the invention is in particular a model or sub-model of an industrial plant, for example, a process-engineering or production-engineering plant. The plant model preferably maps a plant process or sub-process and comprises one or more model component(s), which can be randomly connected together in terms of process-engineering. Input variable values of a plant process or sub-process can thus be the output variable values of a different plant process or sub-process and these can in turn be the input variable values of a further plant process or sub-process. The plant model thus delivers, for example, values for output variables, such as an output capacity, on the basis of input variable values, for instance of a mass flow rate. The plant model is preferably parameterized, where it is possible for process conditions to be defined, for example, by the choice of (process) parameters or process variables. Such parameters or process variables can be, for example, temperatures, pressures, valve settings, and/or input capacities.

One embodiment of the invention is based on the approach of automatically ascertaining input variable values and/or parameter values and/or further output variable values for sub-processes of a plant process to be simulated which can be mapped by model components. For this, a user preferably specifies at least one output variable value of the plant process in a desired operating point of the plant. The output variable value can then form the basis of the ascertainment of the input variable values and/or parameter values and/or further output variable values. In other words, known values for output variables or characteristic quantities can serve as the basis for calculation for at least a portion of the input variables and/or parameters and/or further output variables, which influence the sequence of the sub-processes or upon which the sequence of the sub-processes depends. Consequently, the model components can be automatically parameterized based on the at least one specified output variable value. It is thus not necessary for the user to manually perform the laborious parameterization of the model components which can possibly only be expediently performed with special expert knowledge. The plant model can therefore also be parameterized by a non-domain person and be used, for example, for simulation of the plant process.

Conventionally output variables, such as the electrical rated output of the steam power plant, are known to an automation engineer who deals with the control technology of the steam power plant, but not the exact steam mass flow rates and their pressures and/or temperatures in individual turbine stages. The inventive method accordingly permits the electrical rated or output capacity and possibly a few further process values or values of characteristic quantities or output variables and/or input variables to be specified in an operating point of the steam power plant, such as under full load, in order to parameterize a complex model of the steam power plant such that, at least in the operating point, it generates the specified rated output and achieves the further specified process values or further values of characteristic quantities or output variables in this operating point. Unknown parameters, which influence the achievable rated output, can be automatically adjusted and do not have to be manually set by the automation engineer. The steam power plant model parameterized in this way can then be used by the automation engineer as the basis for testing a control system, such as during the course of a simulation.

In particular, continuous use of a single simulation module (of the plant model) over the entire life cycle of a plant can be achieved, also by different users, by ascertaining the input variable values and/or parameter values and/or further output variable values on the basis of at least one specified output variable value in an operating point and model components, which each map physical sub-processes of a plant process.

In a preferred embodiment, the model components correspond to physical models. The model components can thus each map the sub-process of a plant component and, more precisely, preferably with the aid of mathematical equations, which are based on physical connections or describe such connections. Highly accurate and particularly realistic models may be provided by the physical modelling. In particular, error scenarios can also be realistically replicated, which are necessary, for example, for accurate training simulations.

Preferably, each of the physical models is parameterized, with the corresponding parameters defining the process or operating conditions of the respective plant components. The input variables and/or parameters preferably correspond to variables in the mathematical equations. This makes it possible to correctly replicate physical phenomena in the framework of the model accuracy and to map connections physically correctly. In particular, the behavior of the individual plant components may thus be described particularly precisely and reliably even in very different operating points of the plant.

In a further preferred embodiment, at least a portion of the input variable values and/or parameter values and/or further output variable values is back-calculated during ascertaining, preferably to at least one specified operating point. Here, back-calculation should preferably be taken to mean a, in particular mathematical, calculation of a portion of the input variable values and/or parameter values and/or further output variable values based on the at least one specified output variable value. In other words, ascertaining at least a portion of the input variable values and/or parameter values and/or further output variable values is preferably based on mathematical operations, in particular calculation operations. It is, for example, possible to invert the equations describing the plant components, so the at least one output variable, for which a value is specified, can serve as a variable. The plant model, in particular the model components corresponding to physical models, can thus also be managed by non-domain users.

In a further preferred embodiment, the model components have, in particular mathematical, model equations, which are solved to recalculate the input variable values and/or parameter values and/or further output variable values. The model equations can possibly be transformed for this purpose. The model equations can be, for example, difference equations or differential equations. Such model equations, possibly also equation systems comprising a plurality of model equations, can map individual model components or the corresponding sub-processes particularly precisely and physically correctly. In particular, with the aid of the plant model formed from such model components, the plant process can also be reliably and precisely simulated in rarely occurring operating points of the plant, such as in the case of faults.

Due to the fact that the plant model or its model components is/are based on mathematical model equations and these are used, such as in transposed form, for a back-calculation, for instance, of unknown parameters, the advantages of a phenomenological (modelling) approach, in which only input variables and output variables are considered and thus a complex parameterization is not necessary, may also be combined with the advantages of a physical approach, which allows an accurate replication of a real plant model. The at least one output variable value can be freely chosen or specified, such as by a user, for any operating point. In this sense, the plant model can be perceived as scalable in its entirety. The at least one specified output variable, for which a value is specified, is then preferably used as a variable in the transformed model equation(s) and at least a portion of the input variable values and/or parameter values and/or further output variable values derived. If increasingly more output variables and/or input variables and/or parameters are then known in further operating points, the accuracy of the plant model can increase. A scalable accuracy is then made possible.

In a further preferred embodiment, difference equations and/or differential equations are transformed in a stationary state, in particular at least partially inverted. Here, (mathematical) model equations, which describe the dynamics of a sub-process, are preferably considered in the stationary state. It is thus possible, for example, to consider sub-processes in dynamic equilibrium, such as in a flow equilibrium, in which substances, particles or energy flow into a system and flow out again to the same extent, and to transform, for example, to invert, the corresponding equations under appropriate conditions of equilibrium. This can simplify the calculations and thus reduce the required computing power or time. In addition, a clear solution to the model equations can thus possibly also be achieved.

A difference equation and/or differential equations can be transferred, for example, into the stationary state, for instance, because the change over time of a variable is set to zero. This allows simple, at least partial solving of the model equations according to the input variables and/or parameters and/or further output variables, for which values are to be ascertained.

In a further preferred embodiment, at least one different portion of the parameter values is specified to ascertain at least a first portion of the input variable values and/or parameter values and/or further output variable values. The different portion of the parameter values can be specified by a user, in particular manually, for instance, by acquiring a user input, or automatically, for instance, by reading from a database. This makes it possible to ensure that the model equations can be solved. In particular, it is possible to ensure that clear values can be ascertained for the remaining first portion of the input variables and/or parameters and/or further output variables, for example, by back-calculation based on transformed model equations while taking into account the different portion of the input variables and/or parameters and/or output variables, for which values are specified.

In a further preferred embodiment, at least a second portion of the input variable values and/or parameter values and/or further output variable values is automatically specified based on a specified operating point of the plant and preferably forms the basis of the ascertainment of the first portion of the input variable values and/or the parameter values and/or the further output variable values. In other words, assumptions are preferably made for at least a second portion of the input variables and/or parameters and/or output variables used in the plant components or incorporated in the corresponding model equations. These assumptions are preferably based on the specified operating point of the plant. The specified operating point can correspond in particular to the specified output variable value. This can significantly simplify and/or accelerate the use of the plant model, in particular for a non-domain user.

The second portion of the input variable values and/or parameter values and/or further output variable values preferably map process conditions, such as pressures, temperatures and/or mass flow rates, which characterize the specified operating point, in particular are typical and/or necessary for operation of the plant in this operating point. If the specified output variable value corresponds, for example, to a maximum output capacity of the plant, a maximum degree of opening of a valve, a maximum rotational speed of a shaft, and/or a maximum conveying capacity of a pump can be specified. Alternatively or in addition, it is conceivable to link parameter values to possible operating points of the plant in a database, so when specifying an operating point, the parameter values to be correspondingly specified are reliably and quickly available.

In a further preferred embodiment, at least a third portion of the input variable values and/or parameter values and/or further output variable values is acquired in a parameterizing mode via a user interface and preferably forms the basis for determining the first portion of the input variable values and/or the parameter values and/or the further output variable values. In other words, ascertainment of the first portion of the input variable values and/or the parameter values and/or the further output variable values is based on parameter values preferably specified by the user. Consequently the parameterization of the plant model may be improved further. If the user only has, for example, appropriate expert knowledge in a sector that relates to some of the plant process or only some of the plant components, in this way he can manually stipulate at least selected parameters, in other words determine their values.

In a further preferred embodiment, the plant process is simulated based on the ascertained input variable values and/or parameters and/or further output variable values. In other words, the plant model parameterized in this way can form the basis of a simulation of the plant. This allows non-domain persons to also perform simulations of the plant, for example, in different phases of the life cycle of the plant.

In a further preferred embodiment, user inputs acquired in a simulation mode via a user interface form the basis of the simulation of the plant process. It can be the same user interface via which the user can possibly specify the third portion of the parameter values. The user can thus vary, for example, individual input variables and/or parameters and/or further output variable values and examine their impact, in particular on the specified output variable.

It is also an object of the invention to provide a system for parameterization of a plant model in accordance with a second aspect of the invention that includes a user interface, a modeling module and a parameterization module. The user interface is adapted to acquire at least one output variable value in an operating point of a plant, while the modeling module is adapted to provide a model of the plant comprising a plurality of model components, which map physical sub-processes of the plant process. The parameterization module is finally adapted to ascertain input variable values and/or parameter values and/or further output variable values of the sub-processes on the basis of the model components and the at least one specified output variable value.

The system can be established in terms of hardware and/or software. The apparatus can in particular have a, in particular digital, processing unit, preferably linked in terms of data or signaling to a storage system and/or bus system, such as a microprocessor unit (CPU) or a module thereof and/or one or more program(s) or program module(s). The CPU can be adapted to execute commands, which are implemented as a program stored in a storage system, to acquire input signals from a data bus and/or to emit output signals to a data bus. A storage system can have one or more, in particular different, storage media, in particular optical, magnetic, solid state and/or other non-volatile media. A program can be constructed in such a way that it encompasses the methods described here or is capable of implementing them, so the CPU can execute the steps of such methods and can therewith parameterize in particular a plant model.

The user interface preferably has a graphical user interface, for example, an input mask, via which a user can specify or enter the at least one output variable value, possibly also the third portion of the input variable values and/or parameter values and/or further output variable values.

The modeling module is preferably adapted to generate the plant model, for example, because it combines a plurality of specified model components, stored for instance in a memory or a database. Alternatively, the modeling module can also have a communications or data interface via which the modeling module can receive the plant model.

In a preferred embodiment, the system includes a simulation module, which is configured to simulate the plant process on the basis of the ascertained input variable values and/or parameter values and/or further output variable values. This allows non-domain persons to also carry out simulations of the plant, for example, in different phases of the life cycle of the plant.
1. Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.
2.

### BRIEF DESCRIPTION OF THE DRAWINGS

The above-described properties, features and advantages of the invention and the manner in which they are achieved will be explained in more detail in connection with the figures in the following description of exemplary embodiments of the invention. In the figures, the same reference numerals will be used throughout for the same or mutually corresponding elements of the invention, in which:

FIG. 1 shows an exemplary plant model comprising a plurality of model components in accordance with the invention;

FIG. 2 shows an exemplary system for parameterization of a plant model in accordance with the invention; and

FIG. 3 shows an exemplary method for parameterization of a plant model in accordance with the invention.

### DETAILED DESCRIPTION OF THE EXEMPLARY EMBODIMENTS

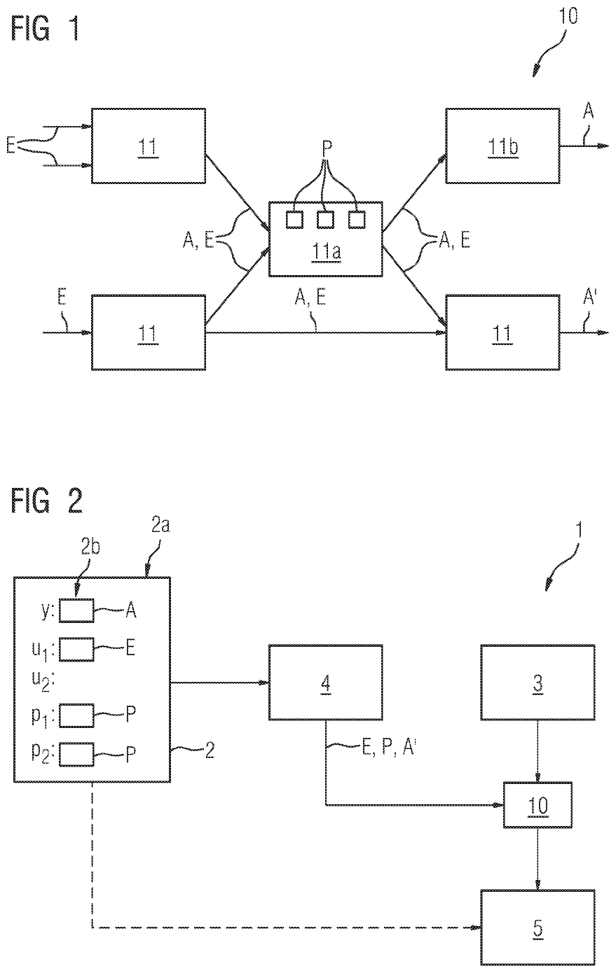

FIG. 1 shows an example of a plant model 10 comprising a plurality of model components 11, which each map a physical sub-process of a plant process, in other words a process implemented the modeled plant. The sub-processes proceed based on input variables, which can assume values E, and parameters, which can assume values P. The sub-processes deliver output variables, which can assume values A. These output variable values A can be perceived as a result of the sub-process proceeding in each case. For reasons of clarity parameter values P are shown only for one plant component 11a.

An output variable of a model component 11 can serve as an input variable of a different model component 11 downstream in the course of the plant process. FIG. 1 shows this by way of example for the model components 11a and 11b. Here, the output variable value A of the model component 11a in the context of the plant model 10 corresponds to the input variable value E of the model component 11b. The sub-processes mapped by the model components 11 thus do not proceed independently of each other. Instead, the course or the process conditions of a preceding sub-process can also influence the sequence of a subsequent sub-process.

For example, the moment generated with the aid of a turbine stage, represented for instance by the plant component 11a, can be decisive for how high the power generated by a generator represented by the model component 11b is.

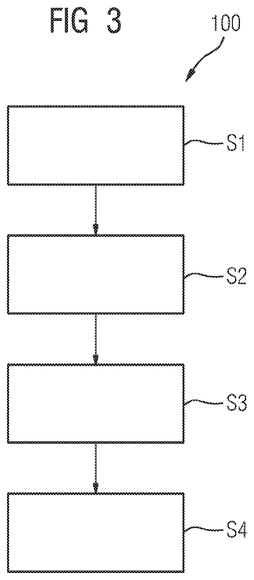

This dependency of the output variables on the input variables and parameters also applies conversely, however, and can be utilized in a method for parameterization of the plant model 10, as is described for example in connection with FIG. 3. At least the input variable values E, possibly also at least some of the parameter values P and/or further output variable values A′, of a plant component 11 can thus be ascertained when at least one output variable value A is specified.

The parameter values P preferably map those relevant process conditions, which can prevail or be set independently of other model components 11 or the sub-processes proceeding there. The parameter values P can alternatively or additionally also characterize the plant component modeled in each case or its properties and/or operating state. Examples of this are an adjustable power introduced into the plant process by the relevant model components 11, for example, a motor power or the power of a cooling system, or an actuator position, for example, the degree of opening of a valve.

The model components 11 can take into account these parameter values P and corresponding input variable values E as well as further output variable values A′, for example, by way of mathematical equations or equation systems. In other words, the plant components can be modelled by such equations or equation systems, with the input variable values E, further output variable values A′ and parameter values P being incorporated as variables.

A plant component can be modeled, for example, by a model component 11 in the form of the following relationship:

\vec{y}=g(\vec{x},\vec{p}₃)+m(\vec{u},\vec{p}₄)

where g and m are functions, y is an output variable, it is an input variable and p₃, p₄ are parameters. y can accordingly assume values A and it values E. p₃, p₄ can assume values P.

The model components 11 can have a further relationship, moreover, which maps the dynamics of the modeled plant component, for instance:

\vec{\dot{x}}=ƒ(\vec{x},\vec{p}₁)+k(\vec{u},\vec{p}₂),

where x describes a state of the plant component and \dot{x} the change over time in the state. Furthermore, p₁, p₂ are parameters, and ƒ and k are functions.

FIG. 2 shows an exemplary system 1 for parameterizing a plant model 10, with a user interface 2, a modeling module 3, a parameterization module 4 and a simulation module 5.

The modeling module 3 is configured to provide the plant model 10 in the form of a plurality of model components, which each map physical sub-processes of a plant process. The modeling module 3 can be established for this purpose as a software module with a graphical user interface, which allows a user to generate the plant model 10, for example, to assemble it from the model components. The model components preferably correspond to predefined or preconfigured model components, which can be assembled in a modular manner. Alternatively or in addition, the model components can be configured, in particular generated, by the user, making it possible for the user to have a particular large amount of freedom in the design of the plant model 10.

Alternatively, it is also conceivable, however, that the modeling module 3 has a communications or data interface, which is adapted to receive a plant model 10 generated, for example, by an external software module. This makes a slim-line system 1 possible.

The model components preferably have equations or equation systems, which reflect the physical properties of the modeled plant components and the physical connections between the plant components or the corresponding sub-processes.

The user interface 2 is configured to acquire at least one output variable value A for an output variable y, specified, for example, by the user. For this purpose, the user interface 2 can likewise have a graphical user interface 2a in which the user can enter the output variable value A, for example, into a corresponding input field 2b.

For each of the model components, the user interface 2 is configured, moreover, to acquire input variable values E for input variables u₁, which are not determined by a different model component, as well as parameter values P for parameters p₁, p₂. By contrast, such input variables u₂, which are determined by different model components 11, are preferably not acquired by the user interface 2. This is indicated in FIG. 2 by no input field 2b being assigned to the input variable u₂.

The parameterization module 4 is configured to ascertain input variable values E and/or parameter values P and/or further output variable values A based on the output variable value A specified with the aid of the user interface 2 and, more precisely, in particular for those input variables u₂ and parameters p₁, p₂, for which no input variable values E or parameter values P were acquired.

For this purpose, the parameterization module 4 can be configured to possibly transform and solve the equations and/or equation systems from the model components. If the solution is not clearly possible, the parameterization module 4 can make assumptions for individual parameter values P not specified by the user and/or input variable values E and/or further output variable values A′ and specify these parameter values P and/or input variable values E and/or further output variable values A′ themselves. The parameterization module 4 can, for example, read corresponding parameter values P from a memory or a database, which are linked there to an operating point of the plant, which preferably corresponds to the specified output variable value A.

The parameterization module 4 can be configured to ascertain the input variable values E and/or parameter values P and/or further output variable values A′ in stationary states \dot{x}=0 of dynamical sub-processes of the model components. A differential equation, which describes the dynamics of a sub-process, for example, by the relationship

\vec{\dot{x}}=ƒ(\vec{x},\vec{p}₁)+k(\vec{u},\vec{p}₂)

can be transformed in the stationary state to

\vec{x}=−ƒ⁻¹(\vec{p}₁)·k(\vec{u},\vec{p}₂)

Here, x describes the state of the plant component and \dot{x} the change over time in the state. ƒ and k are functions. An relationship, which describes the output variable y in accordance with

\vec{y}=g(\vec{x},\vec{p}₃)+m(\vec{u},\vec{p}₄)

can then be solved accordingly for example for ascertaining the input variable u:

\vec{u}=H(\vec{y},\vec{x},\vec{p}₁,\vec{p}₂,\vec{p}₃,\vec{p}₄).

Here, H is a further function, and p₃ and p₄ are further parameters.

The simulation module 5 is finally established to simulate the plant or the operation of the plant, in particular the plant process, based on the plant model 10 parameterized in this way. A coupling of the user interface 2 with the simulation module 5, indicated in FIG. 2 by the broken-line arrow, is conceivable. Consequently, for simulation of the plant process, the user can change one or more input variable value(s) E and/or parameter value(s) P and/or further output variable value(s) A′ for individual model components with the aid of the user interface 2 or, by incorporation in further simulation tools, for example, a control system simulation, can have them change possibly automatically and/or dynamically.

FIG. 3 shows an exemplary method 100 for parameterization of a plant model comprising a plurality of model components, which map sub-processes of a plant process.

The plant model is provided, for example, generated or received, in a method step S1. A modeling module can be provided for this purpose.

The model components of the plant model have input variables and parameter as well as output variables, which influence the sequence or the result of the corresponding sub-processes.

In a method step S2, at least one output variable value of the plant process is specified in an operating point of the plant, for instance by a user with the aid of a user interface. A third portion of the input variable values and/or parameter values and/or further output variables can also be specified if these input variable values and/or parameter values and/or further output variable values are not determined by the plant process or individual sub-processes themselves within the framework of the plant model, in other words are output as an output variable value of a model component or specified as input variable values of a different model component, and are known to the user or the user has the appropriate expert knowledge.

In a further method step S3, input variable values and/or parameter values and/or further output variable values of the sub-processes, in particular a first portion of the input variable values and/or parameter values and/or further output variable values, are ascertained based on the model components and the at least one specified output variable value, in particular based on the basis of a back-calculation. The back-calculation is preferably based on model equations of the model components, which correspond to physical models. These model equations can, where necessary, be transformed and then solved.

If a second portion of the input variables and/or parameter values and/or further output variable values to be ascertained cannot be clearly determined by the back-calculation, in other words no clear solution to the model equations results, these input variable values and/or parameter values and/or further output variable values can also be automatically specified. Alternatively or in addition, the parameter values can also be ascertained based on the third portion of the input variable values and/or parameter values and/or further output variable values specified in method step S2. This makes a reliable automatic parameterization of the plant model possible.

In a further method step S4, the plant or its operation, in particular the plant process, is simulated on the basis of the parameterized plant model.

Thus, while there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-11. (canceled)

12. A method for parameterization of a plant model, the method comprising:
providing a plant model comprising a plurality of model components which map physical sub-processes of a plant process and which correspond to physical models;
specifying at least one output variable value of the plant process in an operating point of the plant; and
ascertaining at least one of input variable values, parameter values and further output variable values of the sub-processes based on the model components and the at least one specified output variable value.

13. The method as claimed in claim 12, wherein at least one portion of at least one of the input variable values, parameter values and further output variable values is back-calculated during said ascertaining.

14. The method as claimed in claim 13, wherein the model components have model equations, which are solved to recalculate at least one of the input variable values, the parameter values and the further output variable values.

15. The method as claimed in claim 14, wherein differential equations are transformed in a stationary state.

16. The method as claimed in claim 12, wherein at least a different portion of at least one of the input variable values, the parameter values and the further output variable values is specified to ascertain at least a first portion of at least one of the input variable values, the parameter values and the further output variable values.

17. The method as claimed in claim 12, wherein a second portion of at least one of the input variable values, the parameter values and the further output variable values is automatically specified based on a specified operating point of the plant.

18. The method as claimed in claim 12, wherein at least a third portion of at least one of the input variable values, the parameter values and the further output variable values is acquired in a parameterizing mode via a user interface.

19. The method as claimed in claim 12, further comprising:
simulating the plant process based on at least one of the ascertained input variable values, parameters and the further output variable values.

20. The method as claimed in claim 19, wherein user inputs acquired in a simulation mode via a user interface form a basis of the simulation of the plant process.

21. A system for parameterization of a plant model, comprising:
a user interface which is configured to acquire at least one output variable value in an operating point of a plant;
a modeling module which is configured to create a model of the plant from a plurality of model components which map physical sub-processes of the plant process and which correspond to physical models; and
a parameterization module which is configured to ascertain at least one of input variable values, parameter values and further output variable values of the physical sub-processes based on the model components and the at least one specified output variable value.

22. The system as claimed in claim 21, further comprising:
a simulation module which is configured to simulate the plant process based on at least one of the ascertained input variable values, the ascertained parameter values and the ascertained further output variable values.
